(19) United States
(12) Patent Application Publication
(10) Pub. No.: US 2018/0267159 A1
(43) Pub. Date: Sep. 20, 2018

(54) SIGNAL GENERATOR

(71) Applicant: MITSUBISHI ELECTRIC CORPORATION, Tokyo (JP)

(72) Inventors: Osamu WADA, Tokyo (JP); Hiroyuki MIZUTANI, Tokyo (JP); Kenichi TAJIMA, Tokyo (JP); Morishige HIEDA, Tokyo (JP)

(73) Assignee: MITSUBISHI ELECTRIC CORPORATION, Tokyo (JP)

(21) Appl. No.: 15/761,337

(22) PCT Filed: Oct. 1, 2015
(86) PCT No.: PCT/JP2015/077927

§ 371 Date: Mar. 19, 2018

(51) Int. Cl. G01S 13/34; G01S 7/40; H03L 7/089; H03L 7/197; H03L 7/185

(52) U.S. Cl. CPC G01S 13/34; G01S 7/40; H03L 2207/12; H03L 7/197; H03L 7/185; H03L 7/089

(57) ABSTRACT

A signal generator according to the invention includes: a reference signal source configured to output a clock signal; a phase locked loop (PLL) circuit configured to generate a chirp signal as a feedback loop type circuit including a frequency divider using the clock signal; and a linearity-improvement processor configured to detect a frequency of a chirp signal of an M-th period generated by the PLL circuit where M is an integer greater than or equal to 1, and to control a division ratio of the frequency divider such that a difference between a frequency of a chirp signal generated in (M+1)-th and subsequent periods in the PLL circuit and a desired frequency becomes smaller than a difference between the detected frequency and the desired frequency.

### TECHNICAL FIELD

The present invention relates to a signal generator which is a circuit that generates a signal waveform.

### BACKGROUND ART

Signal generators are circuits capable of generating a desired signal waveform or a signal of a desired frequency. For example, a signal generator is configured using a phase locked loop (PLL) circuit, a direct digital synthesizer (DDS), or the like.

PLL circuits include a voltage controlled oscillator (VCO), a frequency divider, a loop filter (LF), a phase frequency detector (PFD), and a reference signal source. PLL circuits compares the phase of a signal obtained by dividing the frequency of an output signal of a voltage controlled oscillator (VCO), with the phase of the reference signal source, and feeds back a current or a voltage corresponding to the resulting error to the VCO through the LF to stabilize the oscillation frequency of the VCO.

In frequency modulated continuous-wave radar (FMCW) apparatuses, a chirp signal transmitted by a transmitter is reflected by a detection target object, and the reflected wave is received by a receiver. In the receiver, a mixer mixes the reception signal with a transmission signal transmitted by the transmitter at the time of reception. Since the frequency of an output signal of the mixer is determined by a time difference between the reception signal and the transmission signal, a distance to the detection target object, a relative speed, or the like is calculated from the output signal of the mixer. As a chirp signal for such radar applications, a signal having a time-frequency characteristic of a triangular wave or a sawtooth wave is used. It is necessary that a frequency change with respect to time is linear (frequency is swept linearly with time).

In the case of generating a chirp signal in a PLL circuit, it is known that linearity deteriorates in the vicinity of the maximum point and the minimum point of a chirp signal of a triangular waveform as described in Non-Patent Literature 1, for example.

FIG. 16 is a graph illustrating an example of a time-frequency characteristic of an output signal in a case where a chirp signal of a triangular waveform is generated by a PLL circuit. The horizontal axis represents time, and the vertical axis represents the frequency. Since the PLL circuit has a closed loop configuration and an LF, a delay in response occurs due to a time constant. As a result of the occurrence of delay, overshoot or undershoot occurs in the chirp signal output from the PLL circuit, resulting in deterioration of linearity. Here, the chirp signal output from the PLL circuit is shifted in the time-axis direction and in the frequency-axis direction with respect to a desired chirp signal due to the delay in response.

For example, as the related art for compensating for deterioration of linearity of a chirp signal output from a PLL circuit, Patent Literature 1 describes a configuration of a signal generator using a PLL circuit and a frequency detector. In this signal generator, the time-frequency characteristic of an output signal of a DAC is input to the PLL circuit while allowed to have a triangular waveform representation, and a PFD compares the phase of the output signal of the DAC with the phase of a signal obtained by dividing the frequency of an output signal of the VCO. In this manner, a chirp signal is generated. Furthermore, the V-F characteristic is measured by detecting a control voltage and an output frequency of the VCO, and the time-frequency characteristic of an output signal of the DAC is controlled in such a manner as to compensate for nonlinearity of the V-F characteristic. In this manner, the linearity of a chirp signal is improved.

However, this signal generator has a disadvantage that, even in a case where the compensation for the nonlinear V-F characteristic of the VCO is performed, the compensation for the deterioration of linearity due to the closed loop configuration of the PLL circuit and/or a time constant of the LF cannot be performed.

In Non-Patent Literature 2, as the related art for compensating for the linearity of a chirp signal output from a PLL circuit, a configuration of a signal generator is described in which a PLL circuit and a control unit for measuring a phase of a signal obtained by dividing the frequency of an output signal of a VCO and a phase of an output signal of a reference signal source to control a frequency divider are used. In this signal generator, a transfer function of the PLL circuit is estimated, and a phase of an output signal of the VCO is predicted from the measured phase of the signal obtained by dividing the frequency of the output signal of the VCO. Furthermore, the frequency divider is controlled by using the transfer function in such a manner as to cancel a difference between the predicted phase of the output signal of the VCO and a desired phase of the output signal of the VCO. In this signal generator, it is possible to compensate for deterioration of linearity of a chirp signal due to a closed loop configuration of the PLL circuit or a time constant of the LF.

### CITATION LIST

### Patent Literatures

Patent Literature 1: Japanese Patent Application Publication No. 2014-62824.

### Non-Patent Literatures

Non-Patent Literature 1: S. Ayhan et al., “FPGA Controlled DDS Based Frequency Sweep Generation of High Linearity for FMCW Radar Systems”, Microwave Conference 2012 The 7th German.
Non-Patent Literature 2: M. Pichler et al., “Phase-error Measurement and Compensation in PLL Frequency Synthesizers for FMCW Sensors-II: Theory”, IEEE Transaction on Circuits and Systems-I: Regular Papers.

### SUMMARY OF INVENTION

### Technical Problem

However, in the signal generator of the related art disclosed in Non-Patent Literature 2, since the transfer function of the PLL circuit varies due to a temperature change and/or aged deterioration, linearity of a chirp signal deteriorates as the difference between the estimated transfer function and an actual transfer function increases. For this reason, it is necessary to continue to frequently estimate the transfer function changing every moment. Thus, there is a disadvantage that a radar system needs to be halted while the estimation is performed. As described above, in the related art, there is a disadvantage that it is difficult to compensate for deterioration of linearity of a chirp signal including the influence of a closed loop configuration of a PLL circuit and a time constant of an LF during actual operation of a radar.

The present invention has been devised in order to solve the problems as described above, and it is an object of the present invention to provide a signal generator that compensates for linearity deterioration of a chirp signal including the influence of a closed loop configuration of a PLL circuit and/or a time constant of an LF while a halt of a radar system is avoided.

### Solution to Problem

A signal generator according to the invention includes: a reference signal source configured to output a clock signal; a phase locked loop (PLL) circuit configured to generate a chirp signal as a feedback loop type circuit including a frequency divider using the clock signal; and a linearity-improvement processor configured to detect a frequency of a chirp signal in an M-th period generated by the PLL circuit where M is an integer greater than or equal to 1, and configured to control a division ratio of the frequency divider in a manner that causes a difference between a desired frequency and a frequency of a chirp signal generated in (M+1)-th and subsequent periods in the PLL circuit to become smaller than a difference between the detected frequency and the desired frequency.

### Advantageous Effects of Invention

According to this invention, it is possible to compensate for linearity deterioration of a chirp signal including the influence of a closed loop configuration of a PLL circuit and/or a time constant of an LF while a halt of a radar system is avoided.

### BRIEF DESCRIPTION OF DRAWINGS

FIG. 1 is a configuration diagram illustrating a configuration example of a signal generator 30 according to a first embodiment.

FIG. 2 is a configuration diagram illustrating a configuration example of a linearity-improvement processor 20 according to the first embodiment.

FIG. 3 is a flowchart illustrating an example of an operation of calculating division ratios in the linearity-improvement processor 20 according to the first embodiment.

FIG. 4 is a graph illustrating division ratios of a variable frequency divider 3 in a chirp signal of an M-th period.

FIG. 5 is a graph illustrating a time-frequency characteristic of a chirp signal in the M-th period output from a PLL circuit 10.

FIG. 6 is a graph illustrating N_{M+1}(t+D) calculated by a division ratio calculator 105.

FIG. 7 is a configuration diagram illustrating a configuration example of a signal generator 31 according to a second embodiment.

FIG. 8 is a configuration diagram illustrating a configuration example of a linearity-improvement processor 21 according to the second embodiment.

FIG. 9 is a flowchart illustrating an example of a calculation operation of frequency data in the linearity-improvement processor 21 according to the second embodiment.

FIG. 10 is a graph illustrating frequency data input to a DDS 6 in a chirp signal of an M-th period.

FIG. 11 is a graph illustrating k_{M+1}(t+D) calculated by a frequency data calculator 106.

FIG. 12 is a configuration diagram illustrating a configuration example of a signal generator 32 according to a third embodiment.

FIG. 13 is a configuration diagram illustrating a configuration example of a linearity-improvement processor 22 according to the third embodiment.

FIG. 14 is a flowchart illustrating an example of a calculation operation of frequency data in the linearity-improvement processor 22 according to the third embodiment.

FIG. 15 is a graph illustrating h_{M+1}(t+D) calculated by an f_{LO} calculator 107.

FIG. 16 is a graph illustrating an example of a time-frequency characteristic of an output signal in a case where a chirp signal of a triangular waveform is generated by a PLL circuit.

### DESCRIPTION OF EMBODIMENTS

### First Embodiment

A first embodiment of the present invention will be described below.

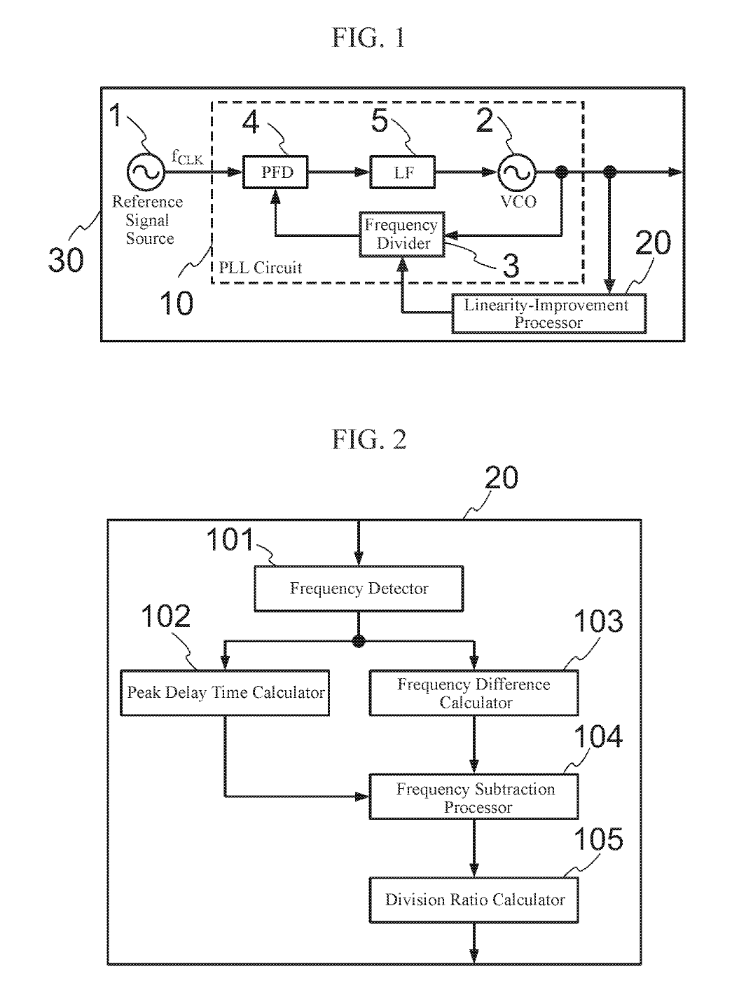

FIG. 1 is a configuration diagram illustrating a configuration example of a signal generator 30 according to a first embodiment. The signal generator 30 includes a reference signal source 1, a PLL circuit 10, and a linearity-improvement processor 20. The PLL circuit 10 includes a VCO 2, a variable frequency divider 3, a PFD 4, and an LF 5. A symbol f_{CLK} represents the frequency of a clock signal output from the reference signal source 1.

The reference signal source 1 is an oscillator that outputs a clock signal of the present signal generator 30. For example, a crystal oscillator, a PLL circuit, or the like capable of outputting an accurate frequency is used as the reference signal source 1. An oscillator of any configuration may be used as the reference signal source 1 as long as the oscillator can output an accurate frequency. An output terminal of the reference signal source 1 is connected to a reference signal input terminal of the PLL circuit 10. The reference signal source 1 oscillates at f_{CLK} and outputs an output signal thereof to the PLL circuit 10.

The VCO 2 is an oscillator that controls the oscillation frequency by the voltage. In the VCO 2, for example, an oscillator that varies the oscillation frequency by a variable capacitance diode is used. The capacitance of the variable capacitance diode is varied in accordance with an applied voltage. As a result, the resonance frequency of a resonance circuit including the variable capacitance diode changes, and the oscillation frequency changes. An oscillator of any configuration may be used as the VCO 2 as long as the oscillation frequency of the oscillator varies in accordance with the voltage. An input terminal of the VCO 2 is connected to an output terminal of the LF 5, and an output terminal of the VCO 2 is connected to an input terminal of the variable frequency divider 3 and an output terminal of the PLL circuit 10.

The variable frequency divider 3 is a circuit that divides the frequency of a signal input from the VCO 2 by N in accordance with a signal indicating the division ratio input from the linearity-improvement processor 20 and outputs a signal of the divided frequency to the PFD 4. Note that N is a real number. In the variable frequency divider 3, for example, a field programmable gate array (FPGA) can be used which is capable of performing the operational processing of a digital signal at a high speed. The variable frequency divider 3 may employ any configuration as long as the configuration enables output of a signal having a frequency which is equal to 1/N times the frequency of an input signal. Moreover, an integer frequency divider or a decimal frequency divider may be used. The input terminal of the variable frequency divider 3 is connected to the output terminal of the VCO 2. A control terminal of the variable frequency divider 3 is connected to a control terminal of the PLL circuit 10, and an output terminal of the variable frequency divider 3 is connected to a comparison signal input terminal of the PFD 4.

The PFD 4 is a circuit that compares phases of a clock signal output from the reference signal source 1 and a signal output from the variable frequency divider 3 and outputs a signal having a pulse width corresponding to the phase difference to the LF 5. The reference signal input terminal of the PFD 4 is connected to a reference signal input terminal of the PLL circuit 10. The comparison signal input terminal of the PFD 4 is connected to the output terminal of the variable frequency divider 3, and an output terminal of the PFD 4 is connected to an input terminal of the LF 5.

The LF 5 is a filter that smoothes a signal of a pulse form output from the PFD 4 and outputs the signal to the VCO 2 as a control voltage of the VCO 2. For example, as the LF 5, a low-pass filter including a capacitor, a resistor, and the like is used. The input terminal of LF 5 is connected to the output terminal of PFD 4, and the output terminal of LF 5 is connected to the input terminal of the VCO 2.

The PLL circuit 10 generates a chirp signal by using a signal indicating the division ratio output from the linearity-improvement processor 20 in synchronization with the clock signal output from the reference signal source 1. The PLL circuit 10 includes the VCO 2, the variable frequency divider 3, the PFD 4, and the LF 5. The reference signal input terminal of the PLL circuit 10 is connected to the output terminal of the reference signal source 1 and the reference signal input terminal of the PFD 4. The control terminal of the PLL circuit 10 is connected to the control terminal of the variable frequency divider 3 and an output terminal of the linearity-improvement processor 20. The output terminal of the PLL circuit 10 is connected to the output terminal of the VCO 2 and an input terminal of the linearity-improvement processor 20.

The linearity-improvement processor 20 is a circuit that detects a frequency of a signal output from the PLL circuit 10, calculates a difference of the frequency with respect to a desired frequency, and outputs a signal indicating the division ratio that causes the difference to be cancelled. The input terminal of the linearity-improvement processor 20 is connected to the output terminal of the PLL circuit 10 and the output terminal of the linearity-improvement processor 20 is connected to the control terminal of the PLL circuit 10.

Although not illustrated in FIG. 1, a feedback loop of the PLL circuit 10 is for reducing a frequency of a signal output from the VCO 2 and inputting the signal to the PFD 4, and thus a frequency converting circuit capable of reducing the frequency may be used in the feedback loop in addition to the variable frequency divider 3. In the frequency converting circuit, for example, a mixer can be used.

FIG. 2 is a configuration diagram illustrating one configuration example of the linearity-improvement processor 20 according to the first embodiment. The linearity-improvement processor 20 includes a frequency detector 101, a peak delay time calculator 102, a frequency difference calculator 103, a frequency subtraction processor 104, and a division ratio calculator 105.

The frequency detector 101 is a circuit that detects the frequency of a chirp signal in the M-th period (hereinafter referred to as f_{M}(t)) output from the PLL circuit 10 at time t and outputs digital data indicating the frequency to the peak delay time calculator 102 and the frequency difference calculator 103. Note that M is a positive integer. An input terminal of the frequency detector 101 is connected to the output terminal of the PLL circuit 10, and an output terminal of the frequency detector 101 is connected to an input terminal of the peak delay time calculator 102 and an input terminal of the frequency difference calculator 103. For example, an analog-to-digital converter (ADC) that converts an analog signal into a digital signal and an FPGA capable of performing operational processing of a digital signal at a high speed are used in combination in the frequency detector 101. Alternatively, a quadrature-demodulation circuit and an FPGA may be used in combination. The frequency detector 101 may employ any configuration as long as the configuration enables detection of the frequency f_{M}(t) of the chirp signal in the M-th period and output of digital data indicating f_{M}(t).

The peak delay time calculator 102 is an operation circuit that calculates a shift in the time-axis direction (hereinafter referred to as τ) between a peak in the time-frequency characteristic of a signal output from the PLL circuit 10 and a peak in the time-frequency characteristic of a desired chirp signal and outputs digital data indicating τ. The peak delay time calculator 102 has a memory for storing a desired output frequency (hereinafter referred to as f_{ideal}(t)) and τ. The input terminal of the peak delay time calculator 102 is connected to the output terminal of the frequency detector 101, and an output terminal of the peak delay time calculator 102 is connected to a time-data input terminal of the frequency subtraction processor 104. For the peak delay time calculator 102, for example, an FPGA capable of performing operational processing of a digital signal at a high speed is used. Any configuration may be employed in the peak delay time calculator 102 as long as the configuration enables calculation of τ and output of digital data indicating T.

The frequency difference calculator 103 is an operation circuit that calculates a difference (hereinafter referred to as Δf(t)) between the frequency of a signal output from the PLL circuit 10 and f_{ideal}(t) at certain time t and outputs digital data indicating Δf(t). The frequency difference calculator 103 has a memory for storing f_{ideal}(t) and Δf(t). The input terminal of the frequency difference calculator 103 is connected to the output terminal of the frequency detector 101, and an output terminal of the frequency difference calculator 103 is connected to a frequency-difference-data input terminal of the frequency subtraction processor 104. In the frequency difference calculator 103, for example, an FPGA capable of performing operational processing of a digital signal at a high speed is used. The frequency difference calculator 103 may employ any configuration as long as the configuration enables calculation of Δf(t) and output of digital data indicating Δf(t).

The frequency subtraction processor 104 is an operation circuit that subtracts a frequency difference Δf(t+τ) at time t+τ from f_{ideal}(t) using the digital data indicating τ output from the peak delay time calculator 102 and the digital data indicating f(t) output from the frequency difference calculator 103. Hereinafter, a frequency obtained by subtracting Δf(t+τ) from f_{ideal}(t) is denoted as f′_{M}(t).

The time-data input terminal of the frequency subtraction processor 104 is connected to the output terminal of the peak delay time calculator 102, and the frequency-difference-data input terminal of the frequency subtraction processor 104 is connected to the output terminal of the frequency difference calculator 103. An output terminal of the frequency subtraction processor 104 is connected to an input terminal of the division ratio calculator 105. In the frequency subtraction processor 104, for example, an FPGA capable of performing operational processing of a digital signal at a high speed is used. The frequency subtraction processor 104 may employ any configuration as long as the configuration enables calculation of f′_{M}(t) and output of digital data indicating f′_{M}(t).

The division ratio calculator 105 is an operation circuit that calculates division ratios in the (M+1)-th period from the digital data indicating f′_{M}(t) output from the frequency subtraction processor 104 and the division ratios in the M-th period. The division ratios in the (M+1)-period are denoted as N_{M+1}(t+D), where D represents time for one period of a chirp signal.

The division ratio calculator 105 has a memory for storing N_{M+1}(t+D) and a memory for storing f_{CLK}. The input terminal of the division ratio calculator 105 is connected to the output terminal of the frequency subtraction processor 104. An output terminal of the division ratio calculator 105 is connected to the control terminal of the PLL circuit 10. For example, an FPGA capable of performing operational processing of a digital signal at a high speed is used as the division ratio calculator 105. The division ratio calculator 105 may employ any configuration as long as the configuration enables calculation of N_{M+1}(t+D) from data indicating f′_{M}(t) and output of digital data indicating N_{M+1}(t+D).

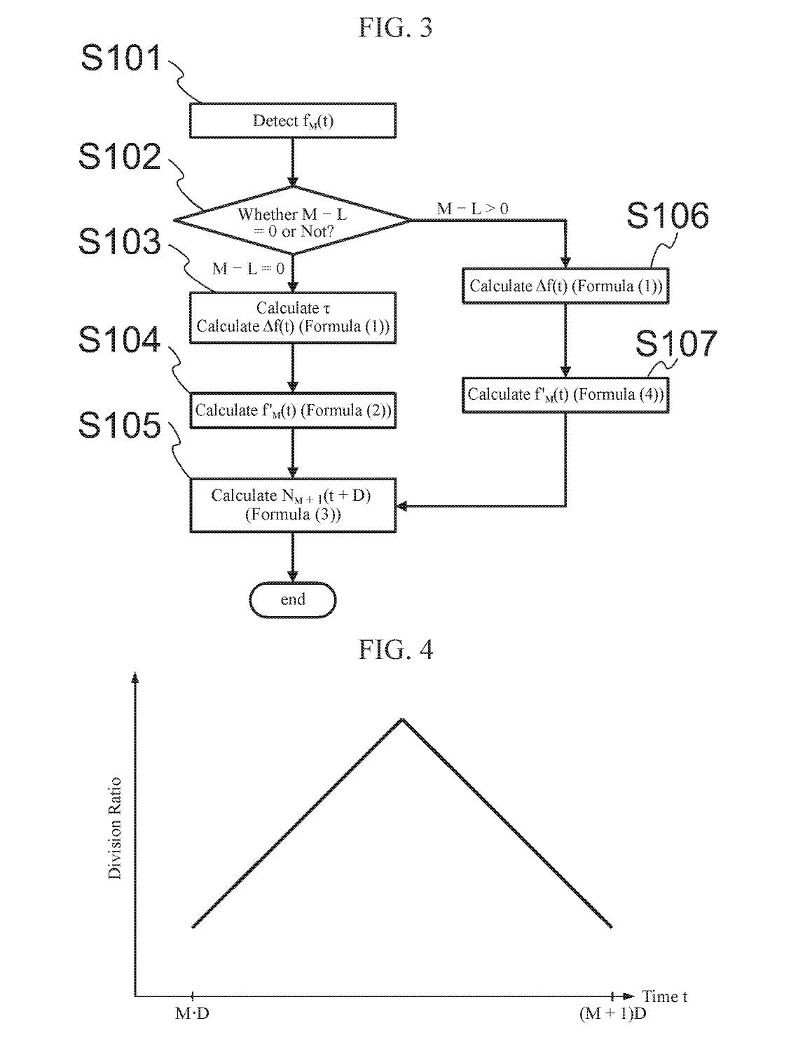

FIG. 3 is a flowchart illustrating an example of an operation of calculating division ratios in the linearity-improvement processor 20 according to the first embodiment. The letter L represents a period in which the operational processing in the linearity-improvement processor 20 has been started, and is a positive integer. In the following explanations, it is assumed that division ratios in the (M+1)-th period are calculated from a chirp signal in the M-th period output from the PLL circuit 10, where 1<L≤M holds. It is further assumed that only the variable frequency divider 3 converts the frequency in the feedback loop of the PLL circuit 10.

First, in step S101, f_{M}(t) is input to the frequency detector 101, and a value thereof is detected. Next, in step S102, the frequency detector 101 determines whether the processing of calculating division ratios in the linearity-improvement processor 20 has been initially performed (M−L=0). If M−L=0 holds, the sequence proceeds to step S103, and if M−L>0 holds, the sequence proceeds to step S106.

Next, in step S103, the peak delay time calculator 102 calculates T, and the frequency difference calculator 103 calculates Δf(t) using formula (1).

Δf(t)=f_{M}(t)−f_{ideal}(t) (1)

Next, in step 104, the frequency subtraction processor 104 calculates f′_{M}(t) according to formula (2) using τ and Δf(t) calculated in step S103.

f′_{M}(t)=f_{ideal}(t)−Δf(t+τ) (2)

Next, in step S105, the division ratio calculator 105 calculates N_{M+1}(t+D) according to formula (3) using f′_{M}(t) calculated in step S104. The division ratio calculator 105 outputs the calculated data to the PLL circuit 10 and terminates the sequence.

$${N}_{M + 1} ( t + D ) = \frac{{f}_{M}^{′} ( t )}{{f}_{CLK}} \qquad ( 3 )$$

In the above step S102, if the frequency detector 101 determines that M−L>0 holds, the sequence proceeds to step S106. In step S106, the frequency difference calculator 103 calculates Δf(t) using formula (1).

Next, in step S107, the frequency subtraction processor 104 calculates f′_{M}(t) by formula (4) using τ calculated in step S103 where M−L=0. Thereafter, the sequence proceeds to step S105. Since the processing of step S105 is as described above, descriptions are omitted here.

f′_{M}(t)=f′_{M-1}(t)−Δf(t+τ) (4)

Next, operations of the signal generator 30 according to the first embodiment will be described. A clock signal output from the reference signal source 1 is input to the PLL circuit 10 and is further input to the PFD 4. A signal of a certain frequency output from the VCO 2 is input to the variable frequency divider 3 and the linearity-improvement processor 20. The variable frequency divider 3 divides the frequency of the signal output from the VCO 2 based on data indicating the division ratios in the M-th period and inputs the signal to the PFD 4. The PFD 4 compares the phase of the signal output from the variable frequency divider 3 and the phase of the signal output from the reference signal source 1 and inputs a signal based on the difference to the VCO 2 via the LF 5.

FIG. 4 is a graph illustrating the division ratios of the variable frequency divider 3 in a chirp signal of an M-th period. The horizontal axis represents time and the vertical axis represents the division ratios. In FIG. 4, in order to simplify descriptions, it is assumed that a chirp signal has a triangular waveform in which an up-chirp and a down chirp are alternately repeated, which also applies to descriptions hereinafter. In order to generate the chirp signal in the PLL circuit 10, the variable frequency divider 3 is controlled by using the division ratios with a triangular waveform representation. Note that it is assumed that one period of a chirp ranges from a point of time when the frequency is the minimum and then rises with time to reach the maximum to a point of time when the frequency drops again to reach the minimum. In FIG. 4, an M-th period ranges from time M·D to (M+1)D.

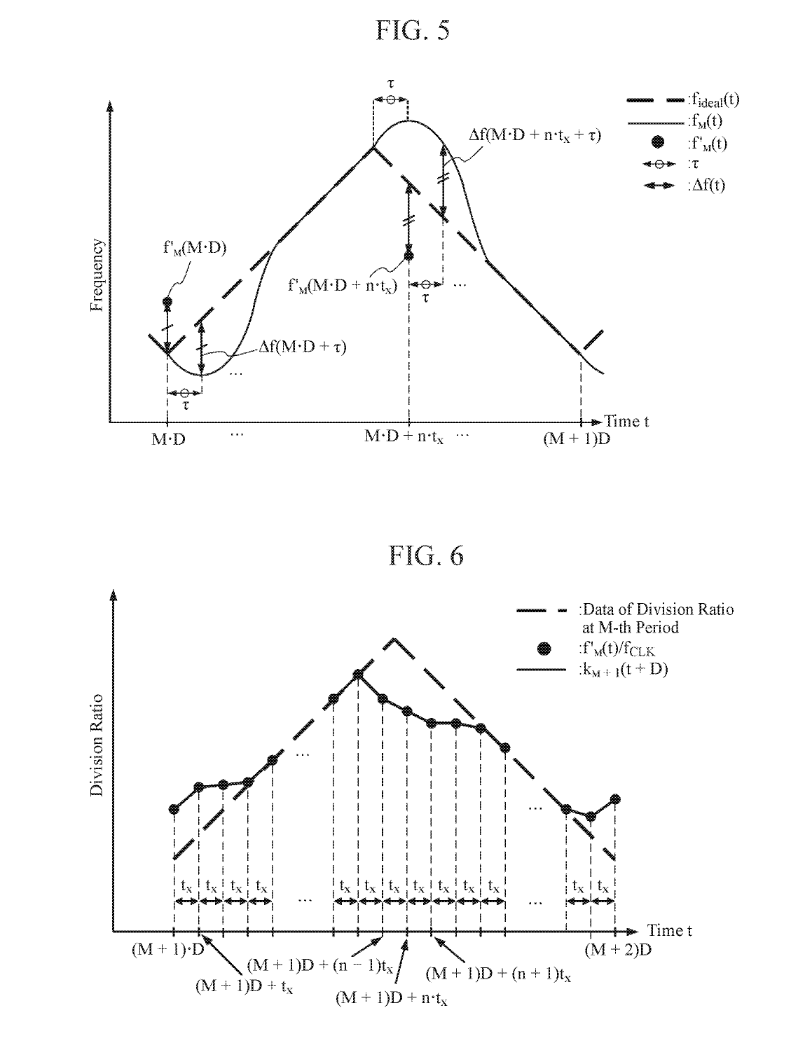

FIG. 5 is a graph illustrating a time-frequency characteristic of a chirp signal in the M-th period output from the PLL circuit 10. The horizontal axis represents time, and the vertical axis represents the frequency. A broken line illustrates f_{ideal}(t) and a solid line illustrates f_{M}(t). Since the PLL circuit 10 has a closed loop configuration and the LF 5, a delay in response occurs due to the time constant. As a result, f_{M}(t) is shifted in the time-axis direction and the frequency-axis direction with respect to f_{ideal}(t).

The peak delay time calculator 102 reads f_{ideal}(t) from the memory for storing f_{ideal}(t) calculates a shift τ in the time-axis direction between a peak of f_{ideal}(t) and a peak of f_{M}(t), and stores τ the memory for storing τ. Note that in FIG. 5, a time difference between the maximum point of f_{ideal}(t) and the maximum point of f_{M}(t) is calculated as τ; however, a time difference between the minimum point of f_{ideal}(t) and the minimum point of f_{M}(t) may be derived as T.

The frequency difference calculator 103 calculates a shift f_{ideal}(M·D)−f_{M}(M·D)=Δf(M·D) in the frequency-axis direction at time M·D. The calculated data is stored in the memory for storing Δf(t). The frequency difference calculator 103 performs this operation from time M·D for every time tₓ. Here, it is assumed that tₓ is a real number and satisfies tₓ>0, tₓ<<D, and A·tₓ=D. Where A is a positive integer. Note that in FIG. 5, for convenience of explanation, only Δf(t) at time M·D and M·D+n·tₓ is illustrated; however, the frequency difference calculator 103 calculates Δf(t) at every time tₓ.

The frequency subtraction processor 104 subtracts Δf(M·D+τ) at time M·D+τ from f_{ideal}(M·D) at time M·D. A frequency obtained by this subtraction is f′_{M}(M·D). At this time, the frequency subtraction processor 104 reads τ from the memory for storing τ and Δf(M·D) from the memory for storing Δf(t). The frequency subtraction processor 104 performs this operation from time M·D for every time tₓ. In FIG. 5, behaviors of subtraction at time M·D and M·D+n·tₓ are illustrated. Note that when f_{ideal}(t+τ)<f_{M}(t+τ) at time t+τ holds, f_{ideal}(t)>f′_{M}(t) holds at time t, and when f_{ideal}(t+τ)>f_{M}(t+τ) holds at time t+τ, f_{ideal}(t)<f′_{M}(t) holds at time t. When f_{ideal}(t+τ)=f_{M}(t+τ) holds at time t+τ, f_{ideal}(t)=f′_{M}(t) holds at time t.

FIG. 6 is a diagram illustrating N_{M+1}(t+D) calculated by the division ratio calculator 105. The vertical axis represents the division ratios, and the horizontal axis represents time. The division ratio calculator 105 reads f_{CLK} from a memory storing f_{CLK} and divides f′_{M}(t) calculated by the frequency subtraction processor 104 by f_{CLK} to derive N_{M+1}(t+D) and stores N_{M+1}(t+D) in the memory. Note that in this case, N_{M+1}(t+D) is calculated at intervals of tₓ. The division ratios in the interval are calculated using linear approximation from division ratios at adjacent times tₓ apart, for example, at M·D+(n−1)tₓ and M·D+n·tₓ.

The PLL circuit 10 reads N_{M+1}(t+D) from the memory storing division ratios and uses N_{M+1}(t+D) as division ratios in the (M+1)-th period. Although the division ratios in the M-th period have a triangular waveform representation, the division ratios in the (M+1)-th period do not have a triangular waveform representation since the division ratios compensate for the response delay due to the time constant of the PLL circuit and have a distorted shape. By allowing the PLL circuit 10 to operate using preliminarily distorted division ratios considering a shift in the time-axis direction and a shift in the frequency-axis direction, the linearity of a chirp signal output from the PLL circuit 10 is improved.

Here, in the case where calculation in the linearity-improvement processor 20 is performed considering only a shift in the frequency-axis direction without considering a shift in the time-axis direction, an error between f_{M+1}(t) and f_{ideal}(t) becomes larger than an error between f_{M}(t) and f_{ideal}(t) and the linearity is thus deteriorated. Therefore, the linearity cannot be improved unless division ratios are determined also in consideration of a shift in the time-axis direction.

In the above description, the process has been described in which the linearity-improvement processor 20 detects and processes the chirp signal in the M-th period, output from the PLL circuit 10, to calculate the division ratios in the (M+1)-th period. The PLL circuit 10 may be controlled the subsequent periods after the (M+1)-th period, using the same N_{M+1}(t+D).

Note that the linearity-improvement processor 20 may continue to operate at L-th and subsequent periods. Alternatively, a circuit for calculating a frequency error between a chirp signal output from the PLL circuit 10 and a desired chirp signal may be included, and, when the frequency error becomes less than or equal to a desired error after the linearity-improvement processor 20 starts operation, the operation may be halted. In the latter case, after the operation of the linearity-improvement processor 20 halts, the PLL circuit 10 is controlled by using division ratios in a period which are last calculated during the operation.

In the above explanation, τ calculated in the L-th period is continuously used for calculation at (L+1)-th and subsequent periods; however, a counter circuit for counting periods of a chirp signal output from the PLL circuit 10 may be included, and division ratios may be brought back to a triangular waveform representation once at a desired period to recalculate τ. Alternatively, a circuit for calculating a frequency error between a chirp signal output from the PLL circuit 10 and a desired chirp signal may be provided, and, when the frequency error becomes larger than or equal to a desired error, division ratios may be brought back to a triangular waveform representation to recalculate τ.

As described above, according to the first embodiment, the chirp signal in the M-th period f_{M}(t) output from the PLL circuit 10 is detected by the linearity-improvement processor 20. Specifically, a shift τ in the time-axis direction and a shift Δf(t) in the frequency-axis direction are calculated, and a frequency f′_{M}(t) is calculated by subtracting a frequency difference Δf(t+τ) from the desired frequency f_{ideal}(t) at time t. Then, the frequency f′_{M}(t) is divided by the output frequency f_{CLK} of the reference signal source 1 to calculate the division ratios N_{M+1}(t+D). By applying the division ratios calculated by the linearity-improvement processor 20 to the frequency divider 3, the PLL circuit 10 is controlled. The response of the PLL circuit 10 is delayed due to the closed loop configuration and the time constant of the LF 5, linearity of the chirp signal is deteriorated, and a shift occurs in the time-axis direction and the frequency-axis direction. In the linearity-improvement processor 20, both the shift τ in the time-axis direction and the shift Δf(t) in the frequency-axis direction are detected, and N_{M+1}(t+D) is calculated using a shift in the frequency direction at a time separated forward in time by T.

In the (M+1)-th period, the PLL circuit 10 operates with the frequency divider 3 using the division ratios N_{M+1}(t+D), thereby improving the linearity. By improving the linearity of a chirp signal by the linearity-improvement processor 20 while the chirp signal is generated by the PLL circuit 10, the linearity deteriorated by the closed loop configuration and the time constant of the LF 5 can be improved without halting operation of a radar.

That is, the signal generator 30 according to the first embodiment includes: the reference signal source 1 for outputting a clock signal; the phase locked loop (PLL) circuit 10 for generating a chirp signal as a feedback loop type circuit including the frequency divider 3 using the clock signal; and the linearity-improvement processor 20 for detecting a frequency of a chirp signal of an M-th (where M is an integer greater than or equal to 1) period generated by the PLL circuit 10 and controlling the division ratio of the frequency divider such that a difference between a frequency of a chirp signal generated in (M+1)-th and subsequent periods in the PLL circuit 10 and a desired frequency is smaller than a difference between the detected frequency and the desired frequency. This configuration enables improvement of the linearity deteriorated by the closed loop configuration and the time constant of the LF 5 without stopping operation of the radar.

Moreover, in the first embodiment, the linearity-improvement processor 20 controls the division ratio of the frequency divider 3 in accordance with the difference between the detected frequency and the desired frequency. Moreover, in the first embodiment, the linearity-improvement processor 20 controls to reduce the division ratio of the frequency divider 3 when the difference between the detected frequency and the desired frequency is positive, and to increase the division ratio of the frequency divider 3 when the difference between the detected frequency and the desired frequency is negative. This configuration enables appropriately bringing the frequency of the chirp signal generated in the (M+1)-th and subsequent periods in the PLL circuit 10 closer to a desired frequency.

Moreover, in the first embodiment, the linearity-improvement processor 20 calculates a delay τ that is measured from a point of time when a peak in the desired frequency is formed to a point of time when a peak in the detected frequency is formed, and, upon controlling the division ratio of the frequency divider 3 at a specific point of time in the (M+1)-th and subsequent periods, uses a difference between the desired frequency and a frequency of a signal generated by the PLL circuit 10 at a point of time separated forward in time by the delay τ from the specific point of time in an L-th period. With this configuration, it is possible to improve the linearity deteriorated by the closed loop configuration and the time constant of the LF 5 considering the influence of the delay caused by the closed loop configuration and the time constant of the LF 5.

### Second Embodiment

In the first embodiment, in order to generate a chirp signal in the PLL circuit 10, by using the division ratios of the variable frequency divider 3 which have a triangular waveform representation, the time-frequency characteristic of a signal input to the comparison signal input terminal of the PFD 4 is allowed to have a triangular waveform. In contrast, in a second embodiment, the time-frequency characteristic of a signal input to the reference signal input terminal of the PFD 4 is controlled to have a triangular waveform.

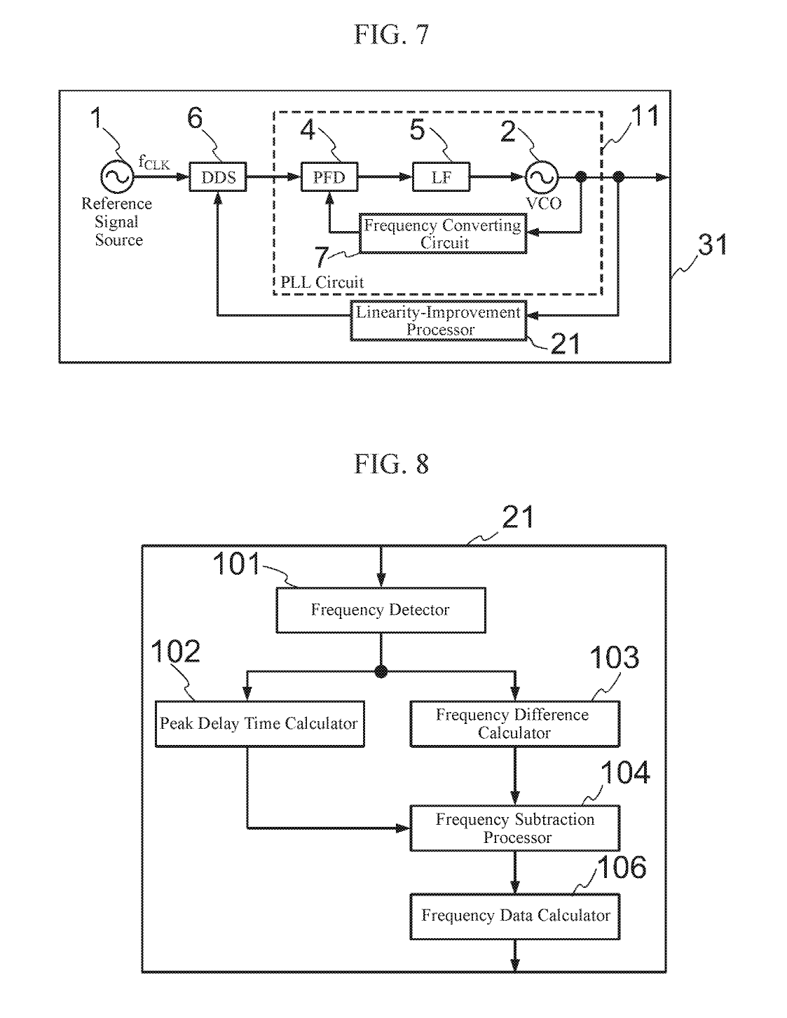

FIG. 7 is a configuration diagram illustrating a configuration example of a signal generator 31 according to the second embodiment. In FIG. 7, the same symbols as those in FIG. 1 denote the same or corresponding parts. In the second embodiment, the time-frequency characteristic of a signal input to the reference signal input terminal of the PFD 4 is controlled to have a triangular waveform using the DDS 6.

The DDS 6 is a circuit for generating an analog signal corresponding to the frequency data output from the linearity-improvement processor 21 in synchronization with the signal output from the reference signal source 1. For example, the DDS 6 includes an adder, a latch, a read only memory (ROM), and a digital to analog converter (DAC). An input terminal of the DDS 6 is connected to an output terminal of the linearity-improvement processor 21, a clock terminal of the DDS 6 is connected to an output terminal of the reference signal source 1, and an output terminal of the DDS 6 is connected to an input terminal of a PLL circuit 11.

The frequency converting circuit 7 lowers the frequency of the signal output from the VCO 2 and inputs the signal to the PFD 4. In the frequency converting circuit 7, for example, a frequency divider, a mixer, and a sample-and-hold circuit are used. The frequency converting circuit 7 may employ any configuration as long as the configuration enables reduction of the frequency of an input signal and output of the signal. Furthermore, in the frequency converting circuit 7, a plurality of types of circuits may be used in combination, for example, by combining a frequency divider and a mixer. An input terminal of the frequency converting circuit 7 is connected to the output terminal of the VCO 2, and an output terminal of the frequency converting circuit 7 is connected to the comparison signal input terminal of the PFD 4.

The PLL circuit 11 is generates a chirp signal in synchronization with a signal output from the DDS 6. The PLL circuit 11 includes the VCO 2, the frequency converting circuit 7, the PFD 4, and the LF 5. The input terminal of the PLL circuit 11 is connected to the output terminal of the DDS 6 and the reference signal input terminal of the PFD 4. An output terminal of the PLL circuit 11 is connected to the output terminal of the VCO 2 and an input terminal of the linearity-improvement processor 21.

The linearity-improvement processor 21 is a circuit that detects a frequency of a signal output from the PLL circuit 11, calculates a difference of the frequency with respect to a desired frequency, and outputs a signal indicating such frequency data that cancels the difference to the DDS 6. The input terminal of the linearity-improvement processor 21 is connected to the output terminal of the PLL circuit 11, and the output terminal of the linearity-improvement processor 21 is connected to the input terminal of the DDS 6.

FIG. 8 is a configuration diagram illustrating one configuration example of the linearity-improvement processor 21 according to the second embodiment. In FIG. 8, the same symbols as those in FIG. 2 denote the same or corresponding parts. The linearity-improvement processor 21 includes a frequency detector 101, a peak delay time calculator 102, a frequency difference calculator 103, a frequency subtraction processor 104, and a frequency data calculator 106. Note that in the following description, it is assumed that the frequency converting circuit 7 is a frequency divider that converts the frequency of an input signal into 1/R of the frequency for output, where R represents a real number and is a fixed value.

The frequency data calculator 106 is an operation circuit that calculates frequency data of (M+1) periods from the digital data indicating f′_{M}(t) output from the frequency subtraction processor 104 and frequency data of the M-th period. Frequency data of (M+1) periods is denoted as k_{M+1}(t+D). Here, D represents time for one period of a chirp signal.

The frequency data calculator 106 has a memory for storing k_{M+1}(t+D), B, R, and f_{CLK}. An input terminal of the frequency data calculator 106 is connected to an output terminal of the frequency subtraction processor 104, and an output terminal of the frequency data calculator 106 is connected to an input terminal of the DDS 6. In the frequency data calculator 106, for example, an FPGA capable of performing operational processing of a digital signal at a high speed is used. The frequency data calculator 106 may employ any configuration as long as the configuration enables calculation of k_{M+1}(t+D) from data indicating f′_{M}(t) and output of digital data indicating k_{M+1}(t+D).

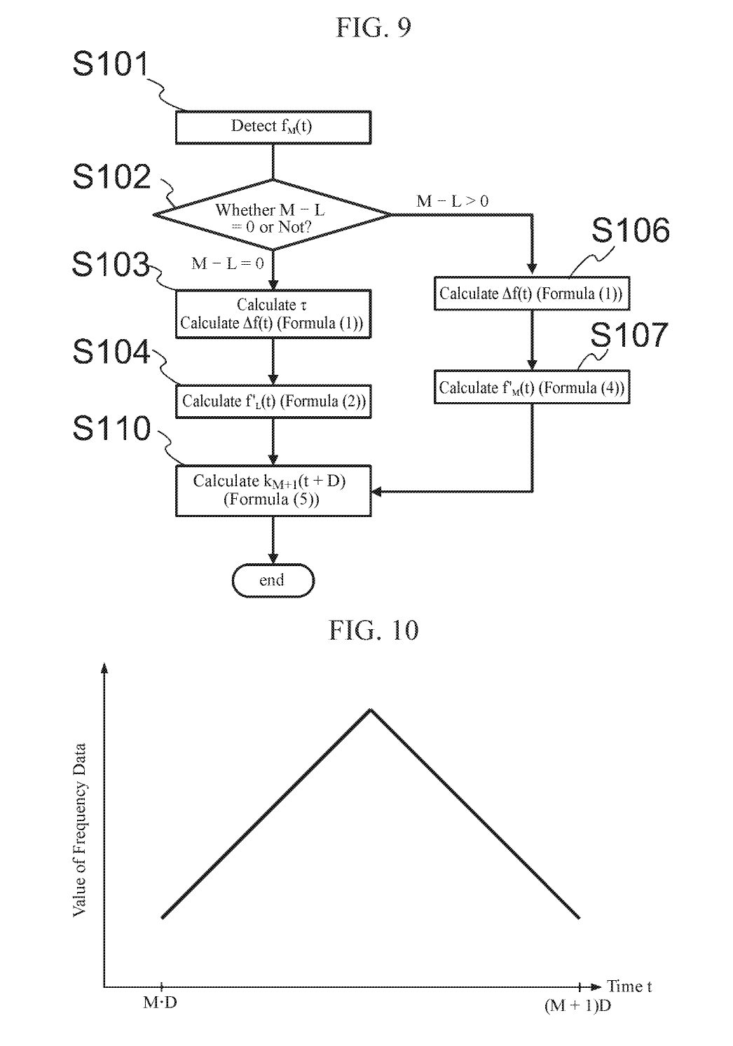

FIG. 9 is a flowchart illustrating an example of a calculation operation of frequency data in the linearity-improvement processor 21 according to the second embodiment. As for FIG. 9, since steps other than step S110 are the same as those in the flowchart described in the first embodiment, only step S110 will be described.

In step S110, the frequency data calculator 106 calculates k_{M+1}(t+D) from formula (5) using f′_{M}(t) calculated in step S104. The frequency data calculator 106 outputs the calculated data to the DDS 6 and terminates the sequence.

$${k}_{M + 1} ( t + D ) = \frac{{f}_{M}^{′} ( t )}{{f}_{CLK}} \cdot \frac{{2}^{B}}{R} \qquad ( 5 )$$

where B represents the word length (bits) of the DDS and is a constant, and f_{CLK} represents the frequency of the clock signal.

Next, operations of the second embodiment will be described. A clock signal output from the reference signal source 1 is input to the DDS 6, and the DDS 6 generates an analog signal from frequency data output from the linearity-improvement processor 21 in synchronization with the signal. The time-frequency characteristic of the output signal of the DDS 6 in an M-th period has a triangular waveform.

The signal output by the DDS 6 is input to the PLL circuit 11 and is further input to the PFD 4. A signal of a certain frequency output from the VCO 2 is input to the frequency converting circuit 7 and the linearity-improvement processor 21. The frequency converting circuit 7 converts the frequency of the signal output from the VCO 2 to 1/R and inputs the signal to the PFD 4. In the PFD 4, the phase of the signal output from the frequency converting circuit 7 and the phase of the signal output from the DDS 6 are compared, and a signal based on the difference is input to the VCO 2 via the LF 5.

FIG. 10 is a graph illustrating frequency data input to the DDS 6 in a chirp signal of an M-th period. The horizontal axis represents time, and the vertical axis represents frequency data. Since the chirp signal is generated by the PLL circuit 11, the DDS 6 is controlled by allowing the frequency data to have a triangular waveform.

In the operations of the second embodiment, since the time-frequency characteristic of the chirp signal in the M-th period output from the PLL circuit 11 is similar to that of the first embodiment, descriptions of the peak delay time calculator 102, the frequency difference calculator 103, and the frequency subtraction processor 104 are omitted.

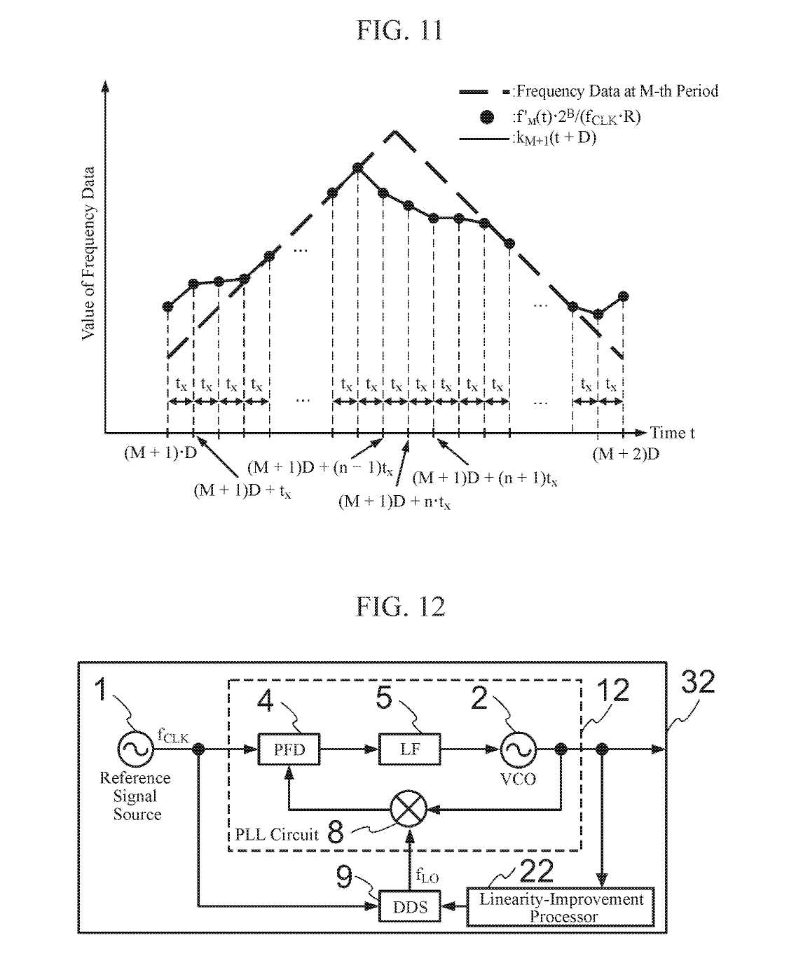

FIG. 11 is a graph illustrating k_{M+1}(t+D) calculated by the frequency data calculator 106. The vertical axis represents frequency data, and the horizontal axis represents time. The frequency data calculator 106 reads each of B, R, and f_{CLK} from the memory for storing B, R, and f_{CLK}, and calculates k_{M+1}(t+D) from the mathematical formula indicated in formula (5) using f′_{M}(t) calculated by the frequency subtraction processor 104. The calculated frequency data is stored in the memory. Note that in this case, k_{M+1}(t+D) is calculated at intervals of tₓ. Frequency data in the interval is calculated using linear approximation from frequency data at adjacent times tₓ apart, for example, at M·D+(n−1)tₓ and M·D+n·tₓ.

The DDS 6 reads k_{M+1}(t+D) from the memory for storing frequency data and uses k_{M+1}(t+D) as frequency data of the (M+1)-th period. Although frequency data of the M-th period has a triangular waveform, frequency data in the (M+1)-th period does not have a triangular waveform since the frequency data compensates for the response delay due to the time constant of the PLL circuit and has a distorted shape. By allowing the DDS 6 to operate using preliminarily distorted frequency data considering a shift in the time-axis direction and a shift in the frequency-axis direction, the time-frequency characteristic of an output signal of the DDS 6 also becomes distorted. By allowing the PLL circuit 11 to operate with the distorted signal, the linearity of a chirp signal output from the PLL circuit 11 is improved.

In the above description, the process has been described in which the frequency data of the (M+1)-th period is calculated with the linearity-improvement processor 21 detecting and calculating the chirp signal of the M-th period output from the PLL circuit 11; however, the DDS 6 may be controlled using the same k_{M+1}(t+D) in the (M+1)-th and subsequent periods.

Note that the linearity-improvement processor 21 may continue to operate at L-th and subsequent periods. Alternatively, a circuit for calculating a frequency error between a chirp signal output from the PLL circuit 11 and a desired chirp signal may be included, and, when the frequency error becomes less than or equal to a desired error after the linearity-improvement processor 21 starts operation, the operation may be halted. In the latter case, after the operation of the linearity-improvement processor 21 halts, the DDS 6 is controlled by using frequency data calculated last during the operation.

In the above explanation, τ calculated in the L-th period is continuously used for calculation at (L+1)-th and subsequent periods; however, a counter circuit for counting periods of a chirp signal output from the PLL circuit 11 may be included, and frequency data may be brought back to a triangular waveform once at a desired period to recalculate τ. Alternatively, a circuit for calculating a frequency error between a chirp signal output from the PLL circuit 11 and a desired chirp signal may be provided, and, when the frequency error becomes larger than or equal to a desired error, frequency data may be brought back to a triangular waveform to recalculate τ.

As described above, according to the second embodiment, the DDS 6 is used to control the time-frequency characteristic of the signal input to the reference signal input terminal of the PFD 4 to be in a triangular waveform. Since the frequency resolution of an output signal of the PLL circuit 11 is improved by using the DDS 6 having a high frequency resolution, the signal generator 31 of the second embodiment can output a signal of finer frequency steps.

That is, the signal generator 31 of the second embodiment includes the reference signal source 1 for outputting a clock signal; the direct digital synthesizer (DDS) 6 for generating an analog signal from the clock signal; the PLL circuit 11 for generating a chirp signal as the feedback loop type circuit using the analog signal generated by the DDS 6; and the linearity-improvement processor 21 for detecting a frequency of the chirp signal of an M-th (where M is an integer greater than or equal to 1) period generated by the PLL circuit 11 and controlling the DDS 6 such that a difference between a frequency of the chirp signal generated in (M+1)-th and subsequent periods in the PLL circuit 11 and a desired frequency is smaller than a difference between the detected frequency and the desired frequency. With this configuration, since the frequency resolution of an output signal of the PLL circuit 11 is improved by using the DDS 6 having a high frequency resolution, the signal generator 31 of the second embodiment can output a signal of finer frequency steps.

### Third Embodiment

In the first embodiment, in order to generate a chirp signal in the PLL circuit 10, by using the division ratios of the variable frequency divider 3 which have a triangular waveform representation, the time-frequency characteristic of a signal input to the comparison signal input terminal of the PFD 4 is allowed to have a triangular waveform. In contrast, in a third embodiment, a mixer is used in a feedback loop of a PLL circuit, and time-frequency characteristic of an LO signal that is a local signal input to the mixer is controlled to have a triangular waveform.

FIG. 12 is a configuration diagram illustrating a configuration example of a signal generator 32 according to the third embodiment. In FIG. 12, the same symbols as those in FIG. 1 or 7 denote the same or corresponding parts. The symbol f_{LO} represents a frequency of a local signal output from a DDS 9. In the third embodiment, the time-frequency characteristic of an LO signal input to a mixer 8 is controlled to have a triangular waveform using the DDS 9.

The DDS 9 is a circuit for generating an analog signal corresponding to the frequency data output from the linearity-improvement processor 22 in synchronization with the clock signal output from the reference signal source 1. For example, the DDS 9 includes an adder, a latch, a ROM, and a DAC. An input terminal of the DDS 9 is connected to an output terminal of the linearity-improvement processor 22, a clock terminal of the DDS 9 is connected to an output terminal of the reference signal source 1, and an output terminal of the DDS 9 is connected to a control terminal of the PLL circuit 12.

The mixer 8 mixes the two input signals and outputs the mixed signal. For example, as the mixer 8, a diode mixer that performs mixing using nonlinearity of diodes is used. An RF terminal of the mixer 8 is connected to an output terminal of the VCO 2, an LO terminal of the mixer 8 is connected to the output terminal of the DDS 9, and an IF terminal of the mixer 8 is connected to a comparison signal input terminal of the PFD 4. The mixer 8 mixes a signal output from the VCO 2 and a signal output from the DDS 9 and outputs the mixed signal to the PFD 4.

Although not illustrated in FIG. 12, a feedback loop of the PLL circuit 12 is for reducing a frequency of a signal output from the VCO 2 and inputting the signal to the PFD 4, and thus a frequency converting circuit capable of reducing the frequency may be used in the feedback loop in addition to the mixer 8. In the frequency converting circuit, for example, a frequency divider or other components can be used.

Although not illustrated in FIG. 12, a CLK variable circuit that varies the frequency of the clock signal output from the reference signal source 1 may be used between the reference signal source 1 and the DDS 9. Since the frequency of a signal that the DDS 9 can output is limited by f_{CLK}, a signal of a higher frequency can be output by raising the frequency of the clock signal input to the DDS 9 using the CLK variable circuit. In the CLK variable circuit, for example, a PLL circuit can be used.

The linearity-improvement processor 22 is a circuit that detects a frequency of a signal output from the PLL circuit 12, calculates a difference of the frequency with respect to a desired frequency, and outputs such frequency data that cancels the difference to the DDS 9. An input terminal of the linearity-improvement processor 22 is connected to an output terminal of the PLL circuit 12, and the output terminal of the linearity-improvement processor 22 is connected to the input terminal of the DDS 9.

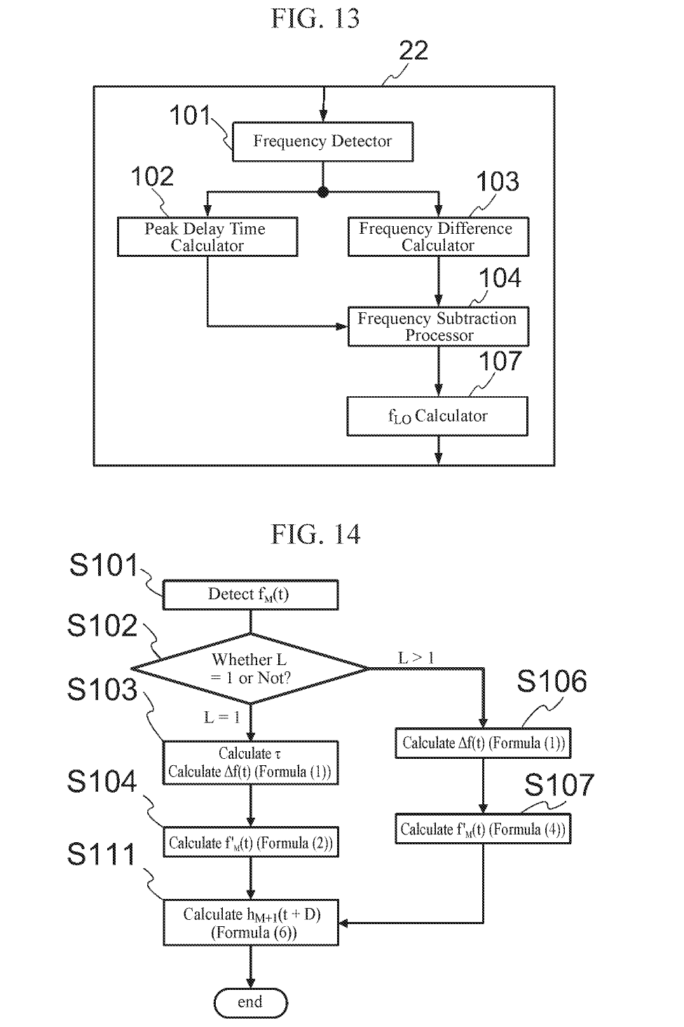

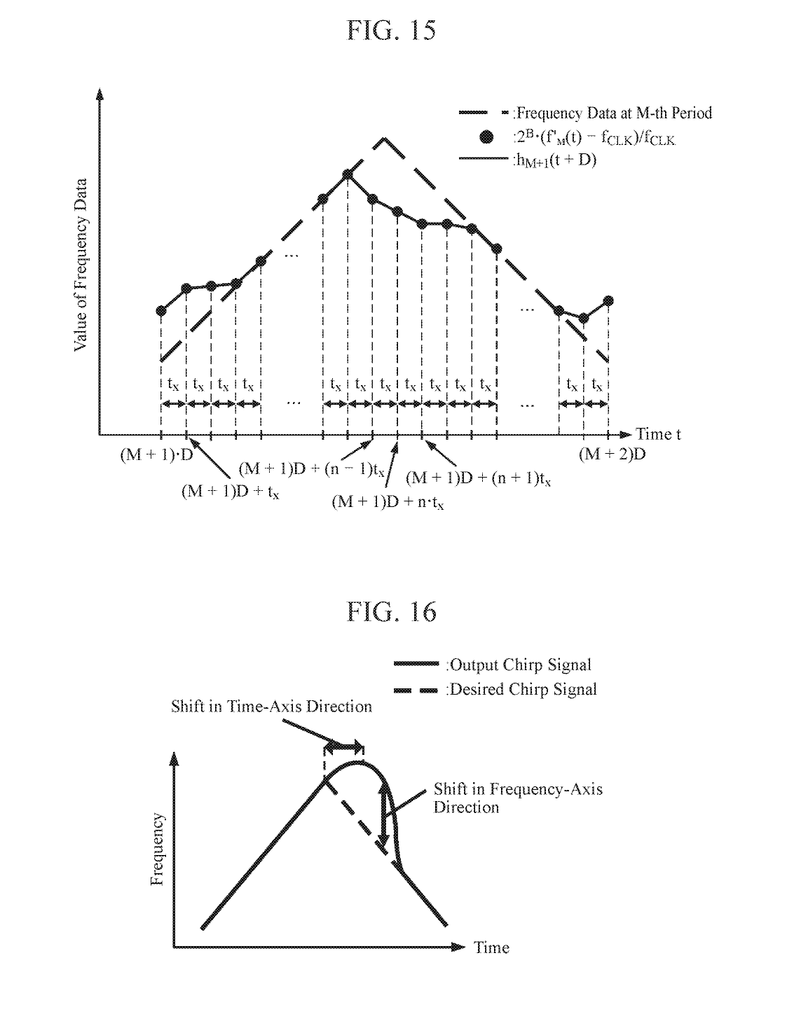

FIG. 13 is a configuration diagram illustrating one configuration example of the linearity-improvement processor 22 according to the third embodiment. In FIG. 13, the same symbols as those in FIG. 2 or 8 denote the same or corresponding parts.

The linearity-improvement processor 22 includes a frequency detector 101, a peak delay time calculator 102, a frequency difference calculator 103, a frequency subtraction processor 104, and an f_{LO} calculator 107.

The f_{LO} calculator 107 is an operation circuit that calculates frequency data of (M+1) periods from the digital data indicating f′_{M}(t) output from the frequency subtraction processor 104 and frequency data of the M-th period. In the present embodiment, frequency data of (M+1) periods is denoted as h_{M+1}(t+D). The letter D represents time of one period of a chirp signal. The f_{LO} calculator 107 has a memory for storing h_{M+1}(t+D), B, and f_{CLK}. An input terminal of the f_{LO} calculator 107 is connected to an output terminal of the frequency subtraction processor 104, and an output terminal of the f_{LO} calculator 107 is connected to the input terminal of the DDS 9. In the f_{LO} calculator 107, for example, an FPGA capable of performing operational processing of a digital signal at a high speed is used. The f_{LO} calculator 107 may employ any configuration as long as the configuration enables calculation of h_{M+1}(t+D) from data indicating f′_{M}(t) and output of digital data indicating h_{M+1}(t+D).

FIG. 14 is a flowchart illustrating an example of a calculation operation of frequency data in the linearity-improvement processor 22 according to the third embodiment. As for FIG. 14, since steps other than step S111 are the same as those in the flowchart described in the first embodiment, only step S111 will be described.

$${h}_{M + 1} ( t + D ) = {2}^{B} \cdot \frac{( {f}_{M}^{′} ( t ) - {f}_{CLK} )}{{f}_{CLK}} \qquad ( 6 )$$

In step S111, the f_{LO} calculator 107 calculates h_{M+1}(t+D) from formula (6) using f′_{M}(t) calculated in step S104. The f_{LO} calculator 107 outputs the calculated data to the DDS 9 and terminates the sequence.

Here, B represents the word length (bits) of the DDS and is a constant, and f_{CLK} represents the frequency of the clock signal.

Next, operations of the third embodiment will be described. A clock signal output from the reference signal source 1 is input to the DDS 9, and the DDS 9 generates an analog signal from frequency data output from the linearity-improvement processor 22 in synchronization with the signal. The time-frequency characteristic of the output signal of the DDS 9 in an M-th period has a triangular waveform.

The signal output from the DDS 9 is input to the PLL circuit 12 and is further input to the mixer 8. Moreover, the VCO 2 outputs a signal of a certain frequency and inputs the signal to the mixer 8 and the linearity-improvement processor 22. The mixer 8 uses the signal of the frequency f_{LO} output from the DDS 9 as an LO signal to convert the frequency of the signal output from the VCO 2 into a low frequency and inputs the signal to the PFD 4. In the PFD 4, the phase of the signal output from the mixer 8 and the phase of the signal output from the reference signal source 1 are compared, and a signal based on the difference is input to the VCO 2 via the LF 5.

In the operations of the third embodiment, since the time-frequency characteristic of a chirp signal in the M-th period output from the PLL circuit 12 is similar to that of the first embodiment, descriptions of the peak delay time calculator 102, the frequency difference calculator 103, and the frequency subtraction processor 104 are omitted.

FIG. 15 is a graph illustrating h_{M+1}(t+D) calculated by the f_{LO} calculator 107. The vertical axis represents frequency data, and the horizontal axis represents time. The f_{LO} calculator 107 reads each of B and f_{CLK} from the memory for storing B and f_{CLK} and calculates h_{M+1}(t+D) from the mathematical formula indicated in formula (6) using f′_{M}(t) calculated by the frequency subtraction processor 104 for storage in the memory. At this time, the frequency data of the (M+1)-th period is calculated at intervals of tₓ. Frequency data in the interval is calculated using linear approximation from frequency data at adjacent times tₓ apart, for example, at M·D+(n−1)tₓ and M·D+n·tₓ.

The DDS 9 reads h_{M+1}(t+D) from the memory for storing frequency data and uses h_{M+1}(t+D) as frequency data of the (M+1)-th period. Although frequency data of the M-th period has a triangular waveform, frequency data in the (M+1)-th period does not have a triangular waveform since the frequency data compensates for the response delay due to the time constant of the PLL circuit 12 and has a distorted shape. By allowing the DDS 9 to operate using preliminarily distorted frequency data considering a shift in the time-axis direction and a shift in the frequency-axis direction, the time-frequency characteristic of an output signal of the DDS 9 also becomes distorted. By allowing the PLL circuit 12 to operate with the distorted signal, the linearity of a chirp signal output from the PLL circuit 12 is improved.

In the above description, the process has been described in which h_{M+1}(t+D) is calculated with the linearity-improvement processor 22 detecting and calculating the chirp signal of the M-th period output from the PLL circuit 12; however, the DDS 9 may be controlled using h_{M+1}(t+D) also in the (M+1)-th and subsequent periods.

Note that the linearity-improvement processor 22 may continue to operate at L-th and subsequent periods. Alternatively, a circuit for calculating a frequency error between a chirp signal output from the PLL circuit 12 and a desired chirp signal may be included, and, when the frequency error becomes less than or equal to a desired error after the linearity-improvement processor 22 starts operation, the operation may be halted. In the latter case, after the operation of the linearity-improvement processor 22 halts, the DDS 9 is controlled by using frequency data calculated last during the operation.

In the above explanation, τ calculated in the L-th period is continuously used for calculation at (L+1)-th and subsequent periods; however, a counter circuit for counting periods of a chirp signal output from the PLL circuit 12 may be included, and frequency data may be brought back to a triangular waveform once at a desired period to recalculate τ. Alternatively, a circuit for calculating a frequency error between a chirp signal output from the PLL circuit 12 and a desired chirp signal may be provided, and, when the frequency error becomes larger than or equal to a desired error, frequency data may be brought back to a triangular waveform to recalculate τ.

As described above, according to the third embodiment, the mixer 8 is used in the feedback loop of the PLL circuit 12, and the time-frequency characteristic of an LO signal input to the mixer 8 is controlled to have a triangular waveform by using the DDS 9. By using the mixer 8 in the feedback loop, phase noise of an output signal of the PLL circuit 12 is reduced as compared to a case of using a frequency divider. Therefore, the signal generator 32 of the third embodiment can output a signal with lower phase noise.

That is, the signal generator 32 of the third embodiment includes: the reference signal source 1 for outputting a clock signal; the PLL circuit 12 for generating a chirp signal as a feedback loop type circuit including the mixer 8 using the clock signal; the DDS 9 for generating a local signal to be input to the mixer 8; and the linearity-improvement processor 22 for detecting a frequency of a chirp signal of an M-th (where M is an integer greater than or equal to 1) period generated by the PLL circuit 12 and controlling a frequency of the local signal generated by the DDS 9 such that a difference between a frequency of a chirp signal generated in (M+1)-th and subsequent periods in the PLL circuit 12 and a desired frequency is smaller than a difference between the detected frequency and the desired frequency. With this configuration, by using the mixer 8 in the feedback loop, phase noise of an output signal of the PLL circuit 12 is reduced as compared to a case of using a frequency divider. Therefore, the signal generator 32 of the third embodiment can output a signal with lower phase noise.

### REFERENCE SIGNS LIST

1: Reference signal source; 2: VCO; 3: Variable frequency divider; 4: PFD; 5: LF; 6, 9: DDS; 7: Frequency converting circuit; 8: Mixer; 10, 11, 12: PLL circuit; 20, 21, 22: linearity-improvement processor; 30, 31, 32: Signal generator; 101: frequency detector; 102: Peak delay time calculator; 103: Frequency difference calculator; 104: Frequency subtraction processor; 105: Division ratio calculator; 106: Frequency data calculator; and 107: f_{LO} calculator.

1-6. (canceled)

7. A linearity-improvement processor, comprising:
circuitry configured to detect a frequency of a chirp signal generated by a phase locked loop circuit;
circuitry configured to calculate a delay that is measured from a point of time when a peak in a frequency of a desired chirp signal is formed to a point of time when a peak in the detected frequency of the chirp signal is formed; and
circuitry configured to, when the phase locked loop circuit generates a chirp signal at one point of time in a specific period, calculate a division ratio for use in a frequency divider being included in a feedback loop type circuit of the phase locked loop circuit, using a difference between the frequency of the desired chirp signal and the detected frequency of the chirp signal at a point of time separated forward in time by the calculated delay from a point of time corresponding to the one point of time, in a period prior to the specific period.

8. A signal generator, comprising:
the linearity-improvement processor according to claim 7;
a reference signal source configured to output a clock signal; and
the phase locked loop circuit configured to generate the chirp signal using the clock signal.

9. A signal generator, comprising:
a reference signal source configured to output a clock signal;
a direct digital synthesizer configured to generate an analog signal from the clock signal;
a phase locked loop circuit configured to generate a chirp signal as a feedback loop type circuit using the analog signal generated by the direct digital synthesizer; and
a linearity-improvement processor configured to detect a frequency of the chirp signal generated by the phase locked loop circuit, configured to calculate a delay that is measured from a point of time when a peak in a frequency of a desired chirp signal is formed to a point of time when a peak in the detected frequency of the chirp signal is formed, and configured to, when the phase locked loop circuit generates a chirp signal at one point of time in a specific period, calculate data for use in the direct digital synthesizer, using a difference between the frequency of the desired chirp signal and the detected frequency of the chirp signal at a point of time separated forward in time by the calculated delay from a point of time corresponding to the one point of time, in a period prior to the specific period.

10. A signal generator, comprising:
a reference signal source configured to output a clock signal;
a phase locked loop circuit configured to generate a chirp signal as a feedback loop type circuit including a mixer using the clock signal;
a direct digital synthesizer configured to generate a local signal to be input to the mixer; and
a linearity-improvement processor configured to detect a frequency of a chirp signal generated by the phase locked loop circuit, configured to calculate a delay that is measured from a point of time when a peak in a frequency of a desired chirp signal is formed to a point of time when a peak in the detected frequency of the chirp signal is formed, and configured to, when the phase locked loop circuit generates a chirp signal at one point of time in a specific period, calculate data for use in the direct digital synthesizer, using a difference between the frequency of the desired chirp signal and the detected frequency of the chirp signal at a point of time separated forward in time by the calculated delay from a point of time corresponding to the one point of time, in a period prior to the specific period.
